(19) United States
(12) Patent Application Publication
(10) Pub. No.: US 2026/0075911 A1
(43) Pub. Date: Mar. 12, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hyuga SAITO, Nonoichi Ishikawa (JP); Saya FUJINO, Kanazawa Ishikawa (JP); Hiroaki KATOU, Nonoichi Ishikawa (JP); Tatsuya NISHIWAKI, Yokohama Kanagawa (JP); Shinya SATO, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/008,831

(22) Filed: Jan. 3, 2025

(30) Foreign Application Priority Data
Sep. 6, 2024 (JP) 2024-154024

(51) Int. Cl. H10D 64/00; H10D 12/00; H10D 30/66; H10D 62/10

(52) U.S. Cl. CPC H10D 64/117; H10D 12/481; H10D 30/668; H10D 62/127

(57) ABSTRACT

A semiconductor device includes a substrate including a first surface; a semiconductor layer located on the first surface of the substrate; a plurality of field plate electrodes located inside the semiconductor layer, the plurality of field plate electrodes being positioned at vertices of triangles in a plane parallel to the first surface; and a gate electrode positioned between the plurality of field plate electrodes in the plane parallel to the first surface, a pattern of the gate electrode surrounding a periphery of one of the field plate electrodes being hexagonal, the gate electrode including six side surfaces at the periphery of the one of the field plate electrodes, the semiconductor layer including first side surfaces, the first side surfaces being six equivalent crystal planes respectively facing the six side surfaces of the gate electrode.

### CROSS-REFERENCE TO RELATED APPLICATION

This application is based upon and claims the benefit of priority from Japanese Patent Application No.2024-154024, filed on Sep. 6, 2024; the entire contents of which are incorporated herein by reference.

### FIELD

Embodiments described herein relate generally to a semiconductor device.

### BACKGROUND

A power semiconductor device has been proposed in which a honeycomb-shaped trench gate is formed between multiple columnar field plate electrodes in a close-packed arrangement.

### BRIEF DESCRIPTION OF THE DRAWINGS

FIG. 1 is a schematic plan view of a semiconductor device according to an embodiment;

FIG. 2 is an A-A cross-sectional view of FIG. 1; and

FIG. 3 is a schematic plan view of a semiconductor device according to a modification of the embodiment.

### DETAILED DESCRIPTION

According to one embodiment, a semiconductor device includes a substrate including a first surface; a semiconductor layer located on the first surface of the substrate; a plurality of field plate electrodes located inside the semiconductor layer, the plurality of field plate electrodes being positioned at vertices of triangles in a plane parallel to the first surface; and a gate electrode positioned between the plurality of field plate electrodes in the plane parallel to the first surface, a pattern of the gate electrode surrounding a periphery of one of the field plate electrodes being hexagonal, the gate electrode including six side surfaces at the periphery of the one of the field plate electrodes, the semiconductor layer including first side surfaces, the first side surfaces being six equivalent crystal planes respectively facing the six side surfaces of the gate electrode.

Exemplary embodiments will now be described with reference to the drawings. Similar components in the drawings are marked with like reference numerals.

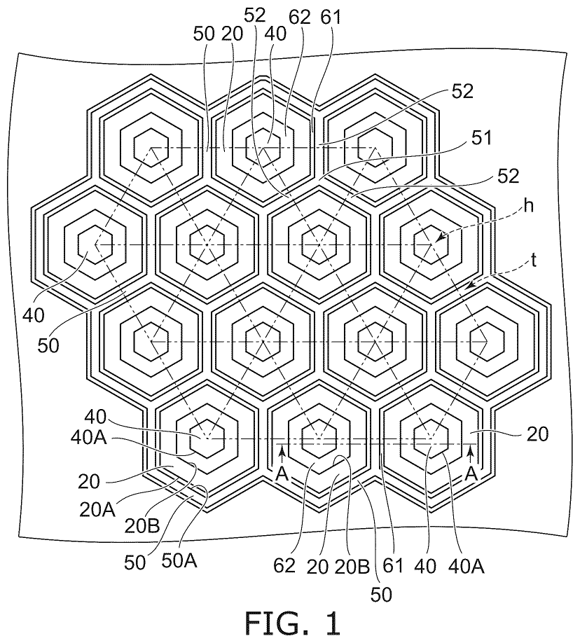

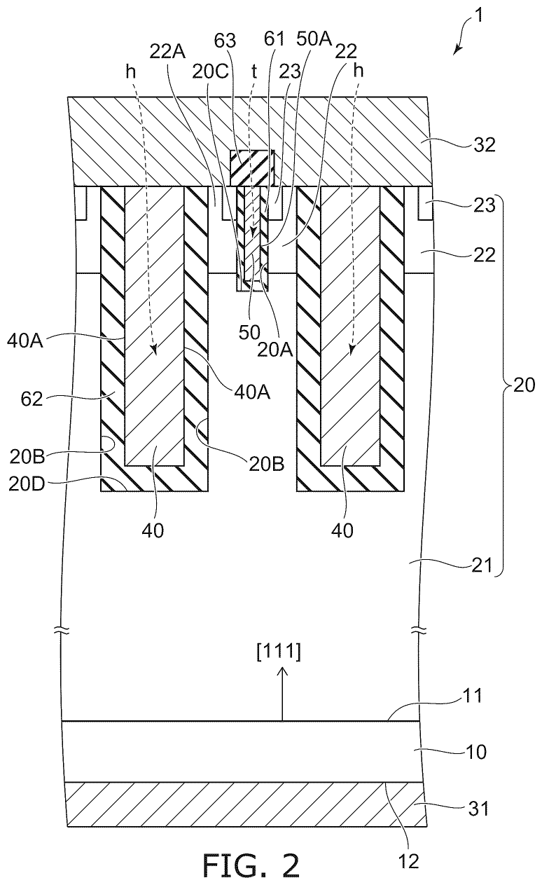

FIG. 1 is a schematic plan view showing an arrangement of major components of a semiconductor device 1 according to an embodiment. FIG. 2 is an A-A cross-sectional view of FIG. 1. A second electrode 32 and an insulating layer 63 that are shown in FIG. 2 are not illustrated in FIG. 1.

As shown in FIG. 2, the semiconductor device 1 according to the embodiment includes a first electrode 31, the second electrode 32, a substrate 10, and a semiconductor layer 20. The substrate 10 and the semiconductor layer 20 are located between the first electrode 31 and the second electrode 32. In the specification, the direction from the first electrode 31 toward the second electrode 32 is taken as up or above; and the direction from the second electrode 32 toward the first electrode 31 is taken as down or below.

The substrate 10 includes a first surface 11, and a second surface 12 positioned at the side opposite to the first surface 11. The second surface 12 contacts the first electrode 31 and is electrically connected with the first electrode 31.

The semiconductor layer 20 is located on the first surface 11 of the substrate 10. Although a first conductivity type is described as an n-type and a second conductivity type is described as a p-type in the semiconductor layer 20 according to the embodiment, the first conductivity type may be the p-type; and the second conductivity type may be the n-type.

The semiconductor layer 20 includes an n-type first semiconductor part 21 located on the first surface 11 of the substrate 10, a p-type second semiconductor part 22 located on the first semiconductor part 21, and an n-type third semiconductor part 23 located on the second semiconductor part 22. The n-type impurity concentration of the third semiconductor part 23 is greater than the n-type impurity concentration of the first semiconductor part 21.

The second electrode 32 is located on the semiconductor layer 20. The third semiconductor part 23 contacts the second electrode 32 and is electrically connected with the second electrode 32. A portion 22A of the second semiconductor part 22 adjacent to the third semiconductor part 23 contacts the second electrode 32.

The semiconductor device 1 according to the embodiment has, for example, a vertical MOSFET (Metal-Oxide-Semiconductor Field-Effect Transistor) structure. In the MOSFET, the first electrode 31 functions as a drain electrode; the second electrode 32 functions as a source electrode; the first semiconductor part 21 functions as a drift layer; the second semiconductor part 22 functions as a base layer; the third semiconductor part 23 functions as a source layer; and the substrate 10 functions as an n-type drain layer having a higher n-type impurity concentration than the first semiconductor part 21.

Or, the semiconductor device according to the embodiment may have a vertical IGBT (Insulated Gate Bipolar Transistor) structure. In the IGBT, the first electrode 31 functions as a collector electrode; the second electrode 32 functions as an emitter electrode; the first semiconductor part 21 functions as a drift layer; the second semiconductor part 22 functions as a base layer; the third semiconductor part 23 functions as an emitter layer; and the substrate 10 functions as a p-type collector layer. In the IGBT, an n-type buffer layer that has a higher n-type impurity concentration than the first semiconductor part 21 may be provided between the substrate 10 (the collector layer) and the first semiconductor part 21 (the drift layer).

The semiconductor device 1 according to the embodiment further includes a gate electrode 50 and a gate insulating film 61.

The gate electrode 50 extends downward from the upper surface of the semiconductor layer 20 positioned at the second electrode 32 side, and is positioned inside the semiconductor layer 20. The gate electrode 50 is located, with the gate insulating film 61 interposed, inside a trench t formed in the semiconductor layer 20. The lower end of the gate electrode 50 is positioned inside the first semiconductor part 21 lower than the p-n junction between the second semiconductor part 22 and the first semiconductor part 21. For example, conductive polycrystalline silicon can be used as the material of the gate electrode 50.

The gate insulating film 61 is located between the gate electrode 50 and the semiconductor layer 20. A side surface 50A of the gate electrode 50 faces the second semiconductor part 22 via the gate insulating film 61.

The semiconductor device 1 according to the embodiment further includes a field plate electrode 40 and a field insulating film 62.

The field plate electrode 40 extends downward from the upper surface of the semiconductor layer 20, and is positioned inside the semiconductor layer 20. The multiple columnar field plate electrodes 40 are located inside the semiconductor layer 20 with the field insulating film 62 interposed. Each field plate electrode 40 is located inside the hole h formed in the semiconductor layer 20 with the field insulating film 62 interposed. The field insulating film 62 is located between the field plate electrode 40 and the semiconductor layer 20.

The field plate electrode 40 does not reach the substrate 10. The lower end of the field plate electrode 40 is positioned inside the first semiconductor part 21. The depth from the upper surface of the semiconductor layer 20 of the hole h in which the field plate electrode 40 is located is greater than the depth from the upper surface of the semiconductor layer 20 of the trench t in which the gate electrode 50 is located. The shortest distance between the first electrode 31 and the lower end of the field plate electrode 40 is less than the shortest distance between the first electrode 31 and the lower end of the gate electrode 50. For example, conductive polycrystalline silicon can be used as the material of the field plate electrode 40.

The semiconductor device 1 according to the embodiment further includes the insulating layer 63. The insulating layer 63 is located between the second electrode 32 and the upper surface of the gate electrode 50.

An n-type channel is formed in the region of the second semiconductor part 22 facing the side surface 50A of the gate electrode 50 when the first potential (e.g., a positive potential) is applied to the first electrode 31, a second potential (e.g., the ground potential) that is less than the first potential is applied to the second electrode 32, and the gate voltage that is not less than the threshold is applied to the gate electrode 50. A current flows between the first electrode 31 and the second electrode 32 via the substrate 10, the first semiconductor part 21, the channel, and the third semiconductor part 23; and the semiconductor device 1 is set to the on-state.

In the off-state of the semiconductor device 1 in which the application to the gate electrode 50 of the voltage that is not less than the threshold is stopped, a depletion layer spreads from the p-n junction between the second semiconductor part 22 and the first semiconductor part 21 and from the boundary between the field insulating film 62 and the first semiconductor part 21; and the breakdown voltage of the semiconductor device 1 is maintained.

For example, the upper portion of the field plate electrode 40 contacts the second electrode 32; and the field plate electrode 40 is electrically connected with the second electrode 32. Or, the field plate electrode 40 may be electrically connected with the gate electrode 50. Such a field plate electrode 40 relaxes the electric field distribution of the first semiconductor part 21 (the drift layer) in the off-state and increases the breakdown voltage of the semiconductor device 1.

As shown in FIG. 1, multiple triangles (in the example, equilateral triangles) virtually illustrated by double dot-dash lines are arranged to contact each other gaplessly in a plane parallel to the first surface 11 of the substrate 10 (when viewed in plan). Each of the multiple field plate electrodes 40 is positioned at a vertex of a triangle. As a result, the gate electrode 50 can be arranged in a honeycomb mesh pattern between the multiple close-packed field plate electrodes 40. By such a configuration, the on-resistance can be less than when the gate electrodes 50 are arranged in a lattice mesh pattern between the multiple field plate electrodes 40 arranged in a square lattice.

The gate electrode 50 is positioned between the multiple field plate electrodes 40 in the plane parallel to the first surface 11 of the substrate 10 (when viewed in plan) and surrounds the periphery of one field plate electrode 40 with a hexagonal (in the example, a regular hexagonal) pattern. The planar pattern of the gate electrode 50 is a honeycomb mesh pattern in which multiple hexagonal patterns are repeated. The gate electrode 50 includes six side surfaces 50A at the periphery of one field plate electrode 40. In the plane parallel to the first surface 11 of the substrate 10, the gate electrode 50 includes an intersection part 51, and extension parts 52 extending from the intersection part 51 in three mutually-different directions. Three extension parts 52 are arranged around the intersection part 51 at a spacing of about 120°.

The semiconductor layer 20 that is positioned inside the hexagonal gate electrode 50 when viewed in plan includes first side surfaces 20A that are six equivalent crystal planes respectively facing the six side surfaces 50A of the gate electrode 50. The first side surfaces 20A correspond to the sidewalls of the trench t in which the gate electrode 50 is located. The first side surface 20A includes the third semiconductor part 23 and the region of the second semiconductor part 22 in which the channel is formed, and includes the region in which the major path of the current in the on-state is formed.

The substrate 10 has a cubic crystal structure and is, for example, a silicon substrate. The first surface 11 of the substrate 10 is a (111) plane. The semiconductor layer 20 is a silicon layer epitaxially grown on the (111) plane of the substrate 10. Accordingly, the plane of the semiconductor layer 20 that is parallel to the first surface 11 of the substrate 10 is the (111) plane. The six first side surfaces 20A of the semiconductor layer 20 positioned inside the hexagonal gate electrode 50 when viewed in plan are planes perpendicular to the (111) plane, and are crystallographically equivalent {110} planes due to the crystal lattice symmetry. A crystallographically equivalent plane means that the arrangement of the atoms and the interatomic spacing of the plane is the same.

Generally, a silicon layer is formed on the (100) plane of a silicon substrate. In such a case, among the six side surfaces of the silicon layer facing the six side surfaces of the gate electrode formed in a honeycomb pattern combining multiple regular hexagons when viewed in plan, two of side surfaces are the plane, and four of the side surfaces are the {470} plane. Characteristic fluctuation of the six side surfaces of the silicon layer that include a combination of such high Miller index planes occurs easily due to channel mobility and/or threshold differences between the plane orientations.

According to the embodiment, the fluctuation of the channel mobility and/or threshold of the six first side surfaces 20A can be reduced by setting all of the six first side surfaces 20A of the semiconductor layer 20 that are positioned inside the hexagonal gate electrode 50 when viewed in plan and respectively face the six side surfaces 50A of the gate electrode to be equivalent crystal planes.

The gate insulating film 61 can be, for example, a silicon oxide film, and can be formed by thermal oxidation after forming the trench t in the semiconductor layer 20. According to the embodiment, the first side surfaces 20A of the semiconductor layer 20, which are the sidewalls of the trench t, are equivalent crystal planes in all of the directions in which the trench t extends when viewed in plan. As a result, the fluctuation of the growth rate of the silicon oxide film between the six first side surfaces 20A described above can be reduced, and the fluctuation of the film thickness of the gate insulating film 61 positioned between the first side surface 20A and the side surface 50A of the gate electrode 50 can be reduced. As a result, the threshold fluctuation, etc., can be reduced.

A third surface 20C of the semiconductor layer 20 that forms the bottom surface of the trench t is parallel to the first surface 11 of the substrate 10, and is the (111) plane. In silicon, the growth rate of a silicon oxide film at the (110) plane and the growth rate of a silicon oxide film at the (111) plane are about the same. Accordingly, the fluctuation can be reduced between the film thickness of the gate insulating film 61 positioned between the first side surface 20A and the side surface 50A of the gate electrode 50 and the film thickness of the gate insulating film 61 positioned between the third surface 20C and the lower end of the gate electrode 50. As a result, local dielectric breakdown of the gate insulating film 61 does not easily occur, and the breakdown voltage can be increased.

According to the embodiment, the field plate electrode 40 extends in a columnar shape inside the semiconductor layer 20 in a direction parallel to the [111] direction. In the example shown in FIG. 1, one field plate electrode 40 is a hexagonal prism including six side surfaces 40A. The semiconductor layer 20 that surrounds one field plate electrode 40 when viewed in plan includes second side surfaces 20B that are six equivalent crystal planes respectively facing the six side surfaces 40A of the field plate electrode 40. The six second side surfaces 20B are perpendicular to the (111) plane (the first surface 11) of the substrate 10 and are equivalent {110} planes.

The field insulating film 62 can be, for example, a silicon oxide film, and can be formed by thermal oxidation after forming the hexagonal hole h in the semiconductor layer 20. According to the embodiment, the six second side surfaces 20B of the semiconductor layer 20, which are the sidewalls of the hole h, are equivalent crystal planes. As a result, the fluctuation of the growth rate of the silicon oxide film between the six second side surfaces 20B can be reduced, and the fluctuation of the film thickness of the field insulating film 62 positioned between the second side surface 20B and a side surface 40A of the field plate electrode 40 can be reduced. As a result, local dielectric breakdown of the field insulating film 62 does not easily occur, and the breakdown voltage can be increased.

A fourth surface 20D of the semiconductor layer 20 forming the bottom surface of the hole h is parallel to the first surface 11 of the substrate 10, and is the (111) plane. As described above, in silicon, the growth rate of the silicon oxide film in the (110) plane and the growth rate of the silicon oxide film in the (111) plane are about the same. Accordingly, the fluctuation can be reduced between the film thickness of the field insulating film 62 positioned between the second side surface 20B and the side surface 40A of the field plate electrode 40 and the film thickness of the field insulating film 62 positioned between the fourth surface 20D and the lower end of the field plate electrode 40. As a result, local dielectric breakdown of the field insulating film 62 does not easily occur, and the breakdown voltage can be increased.

For example, the trench t in which the gate electrode 50 is located can be formed in the semiconductor layer 20 by RIE (Reactive Ion Etching). At this time, the depth of the intersection part at the crossing point of the extension parts of the trench that extend in three different directions when viewed in plan exceeds the depths of the extension parts of the trench. Accordingly, the lower end of the intersection part 51 of the gate electrode 50 is positioned lower than the lower end of the extension part 52.

Between one field plate electrode 40 and the hexagonal gate electrode 50 surrounding the one field plate electrode 40 when viewed in plan, the shortest distance between the center of the intersection part 51 of the gate electrode 50 when viewed in plan and the center of the field plate electrode 40 when viewed in plan is greater than the shortest distance between the center of the field plate electrode 40 and the extension part 52 of the gate electrode 50. Due to such a difference of distances, the electric field from the field plate electrode 40 affects the intersection part 51 of the gate electrode 50 less easily than the extension part 52. By positioning the lower end of the intersection part 51 of the gate electrode 50 lower than the lower end of the extension part 52, the electric field from the field plate electrode 40 can easily act on the lower end of the intersection part 51 of the gate electrode 50; and electric field concentration at the lower end of the intersection part 51 of the gate electrode 50 can be relaxed.

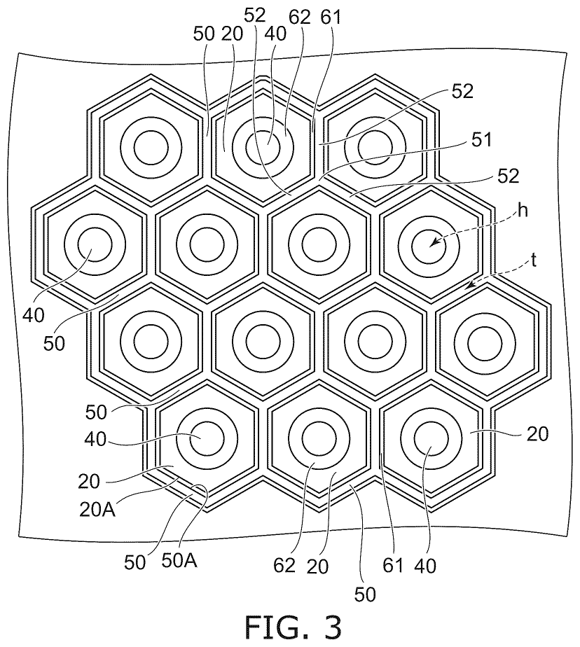

As shown in FIG. 3, the field plate electrode 40 may be circular columnar. The shape of the hole h in which the field plate electrode 40 is located is circular when viewed in plan.

The substrate 10 is not limited to a silicon substrate, and may be, for example, a gallium nitride (GaN) substrate. In such a case, by forming a GaN layer as the semiconductor layer 20 on the c-plane of the GaN substrate as the first surface 11 of the substrate 10, the plane orientations of the first and second side surfaces 20A and 20B of the semiconductor layer 20 described above can be uniform, and can be equivalent m-planes. Also, effects similar to those described above are obtained even when a silicon carbide (SiC) substrate is used as the substrate 10, and a SiC layer is formed as the semiconductor layer 20 on the c-plane of the SiC substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a substrate including a first surface;
a semiconductor layer located on the first surface of the substrate;
a plurality of field plate electrodes located inside the semiconductor layer, the plurality of field plate electrodes being positioned at vertices of triangles in a plane parallel to the first surface; and
a gate electrode positioned between the plurality of field plate electrodes in the plane parallel to the first surface, a pattern of the gate electrode surrounding a periphery of one of the field plate electrodes being hexagonal, the gate electrode including six side surfaces at the periphery of the one of the field plate electrodes,
the semiconductor layer including first side surfaces, the first side surfaces being six equivalent crystal planes respectively facing the six side surfaces of the gate electrode.

2. The device according to claim 1, wherein
the substrate is a silicon substrate,
the semiconductor layer is a silicon layer,
the first surface is a (111) plane, and
the six first side surfaces are {110} planes.

3. The device according to claim 2, wherein
the field plate electrodes extend inside the semiconductor layer in a direction parallel to a [111] direction.

4. The device according to claim 1, wherein
the one of the field plate electrodes is a hexagonal prism including six side surfaces,
the semiconductor layer includes second side surfaces, and
the second side surfaces are six equivalent crystal planes respectively facing the six side surfaces of the one of the field plate electrodes.

5. The device according to claim 4, wherein
the substrate is a silicon substrate,
the semiconductor layer is a silicon layer,
the first surface is a (111) plane, and
the six second side surfaces are {110} planes.

6. The device according to claim 1, wherein
the gate electrode includes an intersection part, and extension parts extending in three mutually-different directions from the intersection part, and
a lower end of the intersection part is positioned lower than lower ends of the extension parts.

7. The device according to claim 1, further comprising:
a first electrode and a second electrode,
the substrate and the semiconductor layer being located between the first electrode and the second electrode.

8. The device according to claim 7, wherein
the substrate includes a second surface positioned at a side opposite to the first surface, and
the second surface contacts the first electrode.

9. The device according to claim 1, wherein
the semiconductor layer includes:
a first semiconductor part located on the first surface of the substrate, the first semiconductor part being of a first conductivity type;
a second semiconductor part located on the first semiconductor part, the second semiconductor part being of a second conductivity type; and
a third semiconductor part located on the second semiconductor part, the third semiconductor part being of the first conductivity type,
a first-conductivity-type impurity concentration of the third semiconductor part being greater than a first-conductivity-type impurity concentration of the first semiconductor part.

10. The device according to claim 9, wherein
the substrate is of the first conductivity type.

11. The device according to claim 9, wherein
the substrate is of the second conductivity type.

12. The device according to claim 9, wherein
the field plate electrodes do not reach the substrate, and
lower ends of the field plate electrodes are positioned inside the first semiconductor part.

13. The device according to claim 7, wherein
a shortest distance between the first electrode and lower ends of the field plate electrodes is less than a shortest distance between the first electrode and a lower end of the gate electrode.

14. The device according to claim 7, wherein
the semiconductor layer includes:
a first semiconductor part located on the first surface of the substrate, the first semiconductor part being of a first conductivity type;
a second semiconductor part located on the first semiconductor part, the second semiconductor part being of a second conductivity type; and
a third semiconductor part located on the second semiconductor part, the third semiconductor part being of the first conductivity type,
a first-conductivity-type impurity concentration of the third semiconductor part being greater than a first-conductivity-type impurity concentration of the first semiconductor part.

15. The device according to claim 14, wherein
the third semiconductor part contacts the second electrode.

16. The device according to claim 14, wherein
the substrate is of the first conductivity type.

17. The device according to claim 14, wherein
the substrate is of the second conductivity type.

18. The device according to claim 14, wherein
the field plate electrodes do not reach the substrate, and
lower ends of the field plate electrodes are positioned inside the first semiconductor part.

19. The device according to claim 14, wherein
a shortest distance between the first electrode and lower ends of the field plate electrodes is less than a shortest distance between the first electrode and a lower end of the gate electrode.

20. The device according to claim 7, wherein
the field plate electrodes contact the second electrode.
